(19) United States
(12) Patent Application Publication
(10) Pub. No.: US 2026/0006739 A1
(43) Pub. Date: Jan. 1, 2026

(54) METHOD FOR PROTECTION OF AN ENCLOSURE FROM AMBIENT CONTAMINATION

(71) Applicants: JOHN J. PAOLUCCIO, MODESTO, CA (US); JOHN A. PAOLUCCIO, MODESTO, CA (US)

(72) Inventors: JOHN J. PAOLUCCIO, MODESTO, CA (US); JOHN A. PAOLUCCIO, MODESTO, CA (US)

(21) Appl. No.: 18/760,015

(22) Filed: Jul. 1, 2024

(51) Int. Cl. H05K 5/06; F25B 21/02; H05K 5/02; H05K 7/20

(52) U.S. Cl. CPC H05K 5/068; F25B 21/02; H05K 5/0212; H05K 7/20309; H05K 7/20318; H05K 7/20336; H05K 7/20381

(57) ABSTRACT

A method for preventing gas flow into and out of a first enclosure having a first volume by limiting changes of the pressure within the first enclosure which includes providing a second enclosure including a variable volume device having an interior second volume that varies responsive to the pressures inside and outside the second enclosure and providing fluid communication between the interior of the first enclosure and the interior of the second enclosure to maintain a substantially fixed collective volume of the combination of the first enclosure and the second enclosure despite ambient temperature.

### PRIORITY

This application is a continuation of U.S. application Ser. No. 18/389,489 filed on Nov. 14, 2023 by John J. Paoluccio et al.

### TECHNICAL FIELD

The present invention is generally directed to methods for protection of enclosures for electrical, electronic, digital, instrumentation, controls, etc. Many industries utilize enclosures to house various equipment and components. The enclosures come in many shapes and sizes along with a broad range of environmental products and accessories to cool, heat, ventilate, filter, and protect the internal components from water including condensation, high humidity, dirt, dust, and other ambient air contaminants. Such enclosures are found in manufacturing facilities, food processing plants, and laboratories of all kinds, in virtually every industry including but not limited to manufacturing, transportation and warehousing, professional, scientific, and technical services, waste management, remediation services, health care, social assistance, and accommodation facilities as well as food services.

Components exposed to undesired conditions may result in damage. For example, a buildup of moisture or condensation, or corrosion, may result in failures, downtime, inaccurate data presentations, electrical shorts, fires, hazards as well as personnel injuries.

The National Electrical Manufacturers Association (NEMA) defines standards used in North America for various grades of electrical enclosures typically used in industrial applications. NEMA enclosure categories include general purpose; drip-tight used where condensation may be severe (as in cooling and laundry rooms), weather-resistant to protect against falling dirt and windblown dust in addition to weather hazards such as rain, sleet and snow, and undamaged by the formation of ice. Weather-resistant enclosures are used outdoors on, for example, ship docks, in construction work, and tunnels and subways.

Enclosures are rated to protect against personal access to hazardous parts, and additional type-dependent designated environmental conditions. A typical NEMA enclosure might be rated to provide protection against environmental hazards such as water, dust, oil, or coolant or atmospheres containing corrosive agents such as acetylene or gasoline. Examples of enclosures for which the present invention has particular application include enclosures defined by the National Electrical Manufacturers Association NEMA 4. That standard requires that the enclosure must exclude at least 65 GPM of water from a 1 in nozzle delivered from a distance not less than 10 ft for 5 min. Applications include outdoors, ship docks, dairies, wastewater treatment plants and breweries.

Enclosures with this rating may be considered tight without leakage in modest wind conditions and no temperature differential. However, all enclosures leak air in and out with a differential pressure. The greater the differential pressure the greater the leakage. Sudden changes in system air temperature will result in a pressure change and depending on the leakage rate the pressure differential may remain for unknown periods until the pressure within the enclosure equals that of ambient air.

Enclosures with this rating may be considered tight without leakage in modest wind conditions and no temperature differential. However, all enclosures leak air in and out with a differential pressure. The greater the differential pressure the greater the leakage. Sudden changes in system air temperature will result in a pressure change and depending on the leakage rate the pressure differential may remain for unknown periods until the pressure within the enclosure equals that of ambient air.

### BACKGROUND OF THE INVENTION

Many firms specialize in custom enclosure designs with protection features to cool, heat, ventilate, and remove moisture with desiccants and other features. Virtually all enclosures will leak air in or out whenever there is a pressure differential between the inside and outside of the enclosure. (An exception, that does not apply to the present invention, would be heating processed food canning jars with lids that at high temperatures expel most of the air through the lid resulting in a vacuum that seals the lid tightly to the jar.)

Enclosures may house electronics, electrical transformers, controls, instruments, optical equipment, computers, switches, gauges, and more. It may have hinged access doors, access panels and see-through ports.

All these protective methods either use electric power for fans and devices or other means to control the internal temperature within certain limits. When desiccants are used, they need frequent replacement. Virtually all enclosures with a fixed volume leak air when there is a change in temperature or elevation that results in a pressure differential. All these prior art methods allow outside air to enter and leave the enclosure to prevent an excessive pressure differential between the interior of the enclosure and outside ambient air. These enclosure system air treatment methods allow ambient air to leak into the enclosure when the system air temperature drops and leak out when the system air temperature increases.

Some of the common prior art methods used to protect enclosures include fans that circulate filtered outside air through the enclosure to help remove excess heat; thermoelectric cooling devices and or heat pipes to remove heat from components; heaters to warm the interior; membrane and filter breathers that allow filtered air to pass through; enclosure louvers, desiccant driers to remove moisture, pressure/vacuum relief valves and combinations of these approaches. The enclosure tightness or ability to not leak air in or out due to a differential in air pressure with ambient air will vary widely depending on the type, quality, NEMA rating, age, gasket type, penetrations into the enclosure, and many other factors.

A typical prior art fixed volume 1,000 cubic inch volume NEMA 4 enclosure may, for example, start at 70° F. and a pressure of 0 psig. When the system air heats up due to internal heat gains and reaches 100° F. or 30° F. degrees higher than ambient air, the system air volume increases. Up to 6% of the original volume or 60 cubic inches would leak out of the enclosure and the pressure may drop back to 0 psig while still at 100F. When the system air cools back down to 70° F. the pressure may drop to −0.06 psig and 60 cubic inches of ambient air will leak back into the enclosure. This process may be repeated multiple times per day and result in significant volumes of ambient air leaking into and out of the enclosure.

If humid ambient air leaks into the enclosure during the day causing the system air to be 75° F. and 50% RH and the ambient air temperature drops to 50° F. at night, the enclosure system air may cool to 50° F. and 100% RH. This would result in significant condensation occurring within the enclosure and on sensitive electronic and electrical connectors. It does not take much of an ambient air temperature drop to result in condensation forming within the enclosure. That is why condensation is considered the most damaging environmental condition to enclosures.

Many enclosures are switching from steel to less expensive polycarbonate. This may also be due to the use of less heat-producing components and more LED lighting containing items. The transmission heat loss from a steel enclosure with ten square feet of surface area may be 300 Btu/h with a 20 F temperature differential. That may be sufficient to remove any excess heat generated within a steel enclosure. Plastic enclosures do not transmit heat as fast as steel.

The prior art enclosures utilize a broad range of methods or solutions to reduce or prevent environmental contamination from airborne contaminants including, water, water condensation, high humidity, frost, mist, snow, rain, salt spray, dust and particles, pollen, chemicals, gasses, low and high temperatures, or excessive heat buildup within the enclosure.

In the prior art apparatus when humid ambient air leaks into the enclosure during the day it may cause the system air to be 75 F and 50% RH. When the ambient air temperature drops to 50 F at night, the enclosure system air may cool to 50F and 100% RH. This would result in significant condensation occurring within the enclosure and on sensitive electronic and electrical connectors. It does not take much of an ambient air temperature drop to result in condensation forming within the enclosure. That is why condensation is considered the most damaging environmental condition to enclosures.

Many enclosures are switching from steel to less expensive polycarbonate. This may also be due to the use of less heat-producing components and more LED lighting containing items. The transmission heat loss from a steel enclosure with ten square feet of surface area may be 300 Btu/h with a 20 F temperature differential. That may be sufficient to remove any excess heat generated within a steel enclosure. Plastic enclosures do not transmit heat as fast as steel. Thus, the advent of plastic enclosures fosters heating issues which fosters pressure issues.

Enclosures with internal high heat-producing components have many options to cool the enclosure. These include Air conditioning units and thermoelectric coolers that cool the internal air without drawing in ambient air. These both require electric power to operate and are costly and require maintenance. Ventilation fans, breather valves, louvers, fans with filters, and desiccants are also used. All these prior art systems allow some outside ambient air to enter the enclosure.

From the above, it is therefore seen that there exists a need in the art to overcome the deficiencies and limitations described herein and above.

### SUMMARY OF THE INVENTION

The shortcomings of the prior art are overcome and additional advantages are provided through a method for preventing gas flow into and out of a first enclosure having a first volume by limiting changes of the pressure within the first enclosure which includes providing a second enclosure including a variable volume device having an interior second volume that varies responsive to the pressures inside and outside the second enclosure and providing fluid communication between the interior of the first enclosure and the interior of the second enclosure to maintain a substantially fixed collective volume in the combination of the first enclosure and the second enclosure despite ambient temperature and/or pressure changes whereby the stability of the gas pressure minimizes movement of gases into or out of the collective volume of the fluid communication, the first enclosure and the second enclosure.

In some forms of the invention the method the step of providing a second enclosure having a second volume that varies responsive to the pressures inside and outside the second enclosure includes providing a bladder. The method may further include providing a desiccant in fluid communication with the first enclosure. The method may further include providing a pressure relief valve in fluid communication with the first enclosure and may further including providing a vacuum relief valve in fluid communication with the first enclosure.

Some embodiments further include providing an air conditioning system for removal of heat from the first enclosure. Other embodiments further include providing a cooperating evaporator and condenser to remove heat from the first enclosure. More particularly, the evaporator and condenser may be parts of a heat pipe or thermoelectric cooler. The evaporator may proximate to the dessicant.

Still other embodiments may further including providing a thermostat to control the temperature within said the first enclosure and a desiccant in fluid communication with the first enclosure as well as a pressure relief valve and/or vacuum relief valve in fluid communication with the first enclosure. Some embodiments include providing an air conditioning system and/or thermoelectric cooling device heat pipe for removal of heat and/or from the first enclosure. Some embodiments provide a thermostat to control the temperature within the first enclosure.

Still other embodiments of the method for preventing gas flow into and out of a first enclosure that has a first volume function by limiting changes of the pressure within the first enclosure which include providing a second enclosure having the interior thereof in fluid communication with the ambient air surrounding the first enclosure and disposed within the first enclosure, the second chamber has a volume that varies responsive to the fluid pressure within and outside of the second enclosure to maintain the pressure of gases within the first enclosure that are outside of the fluid tight chamber despite changes in the temperature of fluids therein whereby the stability of the gas pressure minimizes movement of gases into or out of the apparatus.

This method may further include providing a desiccant in fluid communication with the fluid tight chamber as well as include providing a pressure relief valve and/or vacuum relief valve in fluid communication with the first enclosure

This method may further include one or more apparatus selected from the group consisting of an air conditioning system, a thermoelectric cooling device, and heat pipe for removal of heat from the first enclosure. A thermostat is provided in some cases to control the temperature within the first enclosure.

Other embodiments and aspects of the invention are described in detail herein and are considered a part of the claimed invention.

The recitation herein of desirable objects that are met by various embodiments of the present invention is not meant to imply or suggest that any or all of these objects are present as essential features, either individually or collectively, in the most general embodiment of the present invention or any of its more specific embodiments.

### BRIEF DESCRIPTION OF THE DRAWINGS

The subject matter which is regarded as the invention is particularly pointed out and distinctly claimed in the concluding portion of the specification. The invention, however, both as to organization and method of practice, together with the further objects and advantages thereof, may best be understood by reference to the following description taken in connection with the accompanying drawings in which:

FIG. 1 is a schematic drawing of the invention apparatus located above the top of a new or existing enclosure to protect it from ambient air contamination. The invention apparatus includes a variable volume bladder that is in fluid communication with the system air within the enclosure. The equipment enclosure contains various components that are adversely affected by water and other contaminants in ambient air. The invention apparatus bladder, conduit, cooling chamber, and treatment chamber are all in fluid communication and each has system air within the respective parts. A bladder is sized to, at least, accommodate the volumetric expansion and contraction of the system air due to expected temperature and elevation pressure changes. This helps ensure the enclosure never has a negative or positive air pressure with respect to outside ambient air, no matter the temperature or elevation changes, within certain limits.

FIG. 2 is a schematic drawing of the invention apparatus attached to the top of the equipment enclosure. A cap port connects a conduit to the enclosure to provide fluid communication of the apparatus in accordance with the present invention and system air. Air circulation is accomplished by a heat pipe evaporator portion that cools the warm system air. The cooled system air flows through a treatment chamber and then flows back to mix with the system air within the enclosure. A bladder accommodates system air volume expansion or contraction changes to maintain a common air pressure in and out of the enclosure.

FIG. 3 graphically displays typical average ambient daily temperatures in a 24-hour period. Curve A represents ambient daily temperatures for the median and majority of mild temperatures that may occur, for example, 75% of the days in a year. Curve B represents ambient daily temperatures that may occur, for example, 20% of the days in a year. Curve C represents ambient daily temperatures that may occur, for example, 5% of the days in a year. Line 1 represents the maximum inflation volume of the bladder that accommodates a 5% increase in the system air volume expansion from the enclosure due to a 25° F. temperature rise. Line 2 represents the minimum inflation of the bladder that accommodates the decrease in the system air volume decrease from the enclosure due to a 25° F. temperature drop. The difference in system air volume between Line 1 and Line 2 is 10%. Therefore, in this enclosure example, the bladder is sized at 10% of the system air volume within the enclosure. The enclosure system air pressure and ambient air pressure would remain the same as long as the bladder was not completely full or completely empty. At that point, the pressure would start to increase or decrease until the pressure activated the pressure/vacuum relief valves that may be set, for example, for 0.1 psig. Thus, the pressure/vacuum relief valves will limit maximum or minimum pressure.

FIG. 4 is a schematic representation of another embodiment of the present invention apparatus that shows the bladder within the enclosure instead of being in fluid communication and outside the enclosure as shown in FIG. 1. In this embodiment, the internal air within the bladder is in fluid communication with ambient air. The bladder has an open vent port for fluid communication with ambient air. The cooling chamber and treatment chamber are also within the enclosure. The variation allows the system air volume to vary depending on the volume of the bladder and remain pressure-neutral with respect to ambient air.

FIG. 5 is a schematic of another embodiment of the present invention within a very small enclosure. The small enclosure may, for example, be the size of a cell phone. A small bladder has an inlet port that is in fluid communication with ambient air. The small bladder when fully inflated with ambient air may be, for example, 10% of the volume of the internal system air within the enclosure. The evaporator portion of a heat pipe is shown within a removable perforated cartridge that contains the desiccant, oxygen absorber and filter.

### DETAILED DESCRIPTION

For the purpose of description, the term “system air” is used herein is used to refer to the gas within the apparatus that is within fluid-tight enclosures. It is the “system air” pressure that the present invention stabilizes and controls. In embodiments in which the nitrogen is added through the Schrader valve 60, it will be understood that the term “system air” refers to a totally nitrogen gas.

The invention apparatus 10 allows enclosures 30 that serve electronic, equipment, instruments, electrical, and many other applications, that do not have high heat-producing components, to operate in a passive manner, without the need for electric power, that maintains the same internal enclosure 30 pressure as outside ambient air pressure thereby, virtually preventing air leakage in and out of the enclosure 30. This prevents leakage of water and other airborne contaminants in the ambient air 40 from entering into the enclosure 30. Virtually all prior art enclosures 30 may be occasionally exposed to harsh or adverse environmental conditions that can lead to contamination, corrosion, damage, or failure of internal components and safety problems. The source of these problems relates to air leakage due to differential changes in temperature and pressure between enclosure 30 and ambient air 40 temperature, relative humidity, barometric pressure, and elevation changes. The ambient air 40 contamination problems are greater in harsh environments with wind, rain, hail, fog, storms, dust, factory and industry pollution, marine salt spray, and many other forms of pollution. This invention apparatus 10 can allow many of these enclosure 30 applications to operate leak-free in a passive manner, without the need for electric power or frequent maintenance. This invention apparatus 10 eliminates the primary source of the problem and that is ambient air leakage into the enclosure.

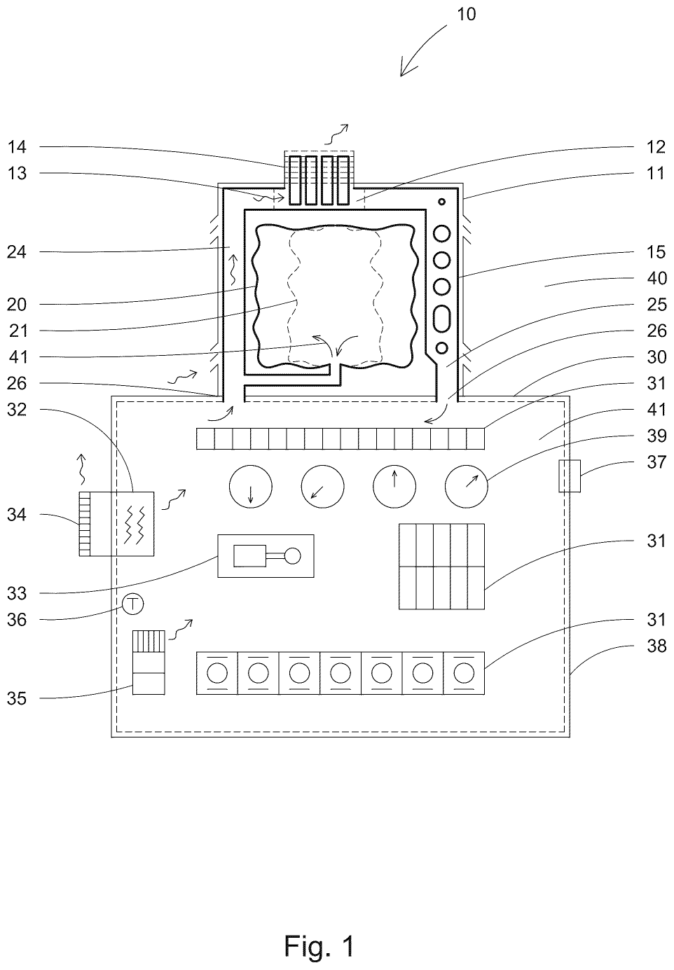

Referring to FIG. 1 an electronic enclosure meeting the NEMA 4 standard has apparatus in accordance with one form of the present invention 10 attached that converts the enclosure 30 into a variable volume enclosure 30 that is in fluid communication with the system air 41 within the enclosure 30. With temperature changes in the system air 41 and the ambient air 40 the system air 41 pressure, temperature, and volume will be governed by the general gas laws. That is essentially: pressure times volume divided by the absolute temperature is a constant.

Since it is desirable to keep the enclosure 30 pressure (P) the same as ambient air pressure, while the temperature (T) changes, the system air 41 volume (V) has to increase or decrease as the temperature changes. In order to allow the system air 41 volume (V) to vary with a fixed enclosure 30 volume it is necessary to supplement the change in system air 41 volume with an auxiliary variable volume device, for example, a bladder that is in fluid communication with the system air.

The invention apparatus 10 is attached to the enclosure 30 with conduits and ports 23, 24, 25, and 26, that are in fluid communication with system air 41. A conduit connection 42 leads to bladder 20 that accommodates system air 41 volumetric expansion and contraction. Accordingly, the expansion and contraction of the variable volume device substantially maintain the system air 41 pressure to be equal to ambient air 40 most of the time. Warm or hot system air 41 rises in conduit 43 to the cooling chamber 44 that contains the evaporator portion 13 of the heat pipe where system air 41 is cooled and the heat energy is transferred to the condenser portion 14 of the heat pipe where the heat energy is transferred to the ambient air 40. The denser cooled system air 44 causes the system air 44 to flow into the treatment chamber 45 which may contain a desiccant 16, oxygen absorber 17, activated carbon 18, and filter 19. As the system air 44 flows over and or through the treatment chamber 45, water molecules are captured by the desiccant 16, oxygen molecules are captured by the oxygen absorber 17 hydrocarbon gas molecules are captured by the activated carbon 18, and particles are captured by the filter 19. The treated system air 46 enters and mixes with system air 41 in enclosure 30. The system air 41 then cools and dries with less oxygen and more inert nitrogen and cleaner and most significantly has same pressure as ambient air 40.

The enclosure 30 in FIG. 1 can accommodate a wide variety of components that may include electronics, transformers, relays, circuit boards, mechanical mechanisms, lights, controls, wires, view ports, gages, switches, and more 31. A heat-producing component 32 is shown in thermal contact with a thermoelectric cooler 34 to directly transfer the generated heat to the ambient air 40. Supplemental cooling for low heat-producing loads is achieved with, for example, a heat pipe chamber 44 that is ideal for removing heat from the circulating system air 41. For certain high heat-producing components 32 thermoelectric coolers 34 are used for removing modest heat outputs directly from specific components 32. Unfortunately, thermoelectric coolers 34 consume a lot of electric power. For large heat output loads, closed air conditioning units may be used. This invention attachment 10 is the preferred form of the invention for adding to new and existing enclosures 30 that need upgrading to help protect the contents of enclosure 30 from ambient air 40 contaminants.

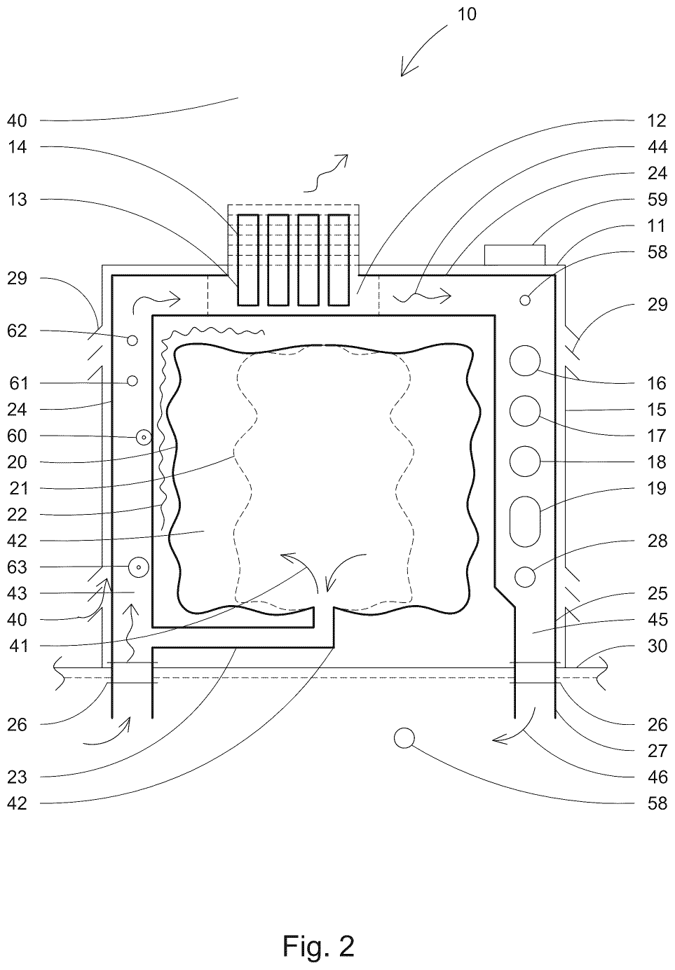

Referring to FIG. 2 shows an enlarged schematic diagram of the invention apparatus 10 that may be more practical for enclosures 30 with less heat-producing components 32. The conduits 23, 24, 25, and 26 are in fluid communication with the system air 41. However, small enclosures 30 may only have one conduit 23 to the bladder 20. The conduit 23 configuration between the invention apparatus 10 and the enclosure 30 may take many other paths as long as it has fluid communication between the cooling chamber 12, treatment chamber 15, and bladder 20 that accommodates the volumetric expansion and contraction of the system air 41 due to temperature changes. The heat pipe chamber 44 shows the evaporator portion of one or more heat pipes 13 with fins. This provides more heat transfer surface area to cool the system air 41. During periods of high humidity, water condensation can form on the evaporator portion of the heat pipe 13, and liquid water and very high-humidity air may flow toward the treatment chamber 15. The bladder 20 sizes may vary depending on application and expected environmental conditions. A common bladder 20 sizes may be 12% the volume of the enclosure 30 to help protect it over a 60 F temperature change.

The apparatus 10 may have an outer enclosure 11 that is ventilated with ambient air. The ambient air has no fluid communication or any impact on the pressure of system air.

The bladder 20 will accommodate the daily normal temperature swings that will allow the system air 41 to remain at ambient air 40 pressure as the system air 41 volume changes from 880 cubic inches to 1120 cubic inches. The lightweight flexible bladder 20 material may, for example, be urethane-coated nylon fabric or other material. Typical bladders so constructed require less than 0.01 psi to inflate. That is far less than the pressure vacuum relief valve 28 settings which is +/−0.1 psig.

The above example was for an enclosure 30 with 1,000 cubic inches internal system air volume 41. The invention apparatus 10 has application for virtually any size enclosure 30 from less than 10 cubic inches to more than 10,000 cubic inches. The system air 41 displacement ratio remains the same no matter the size. The materials of construction such as bladder 20 material may change where small enclosures 30 may have bladders 20 with thinner and lighter weight material whereas very large enclosures 30 may have heavier weight fabric material for the bladder 20.

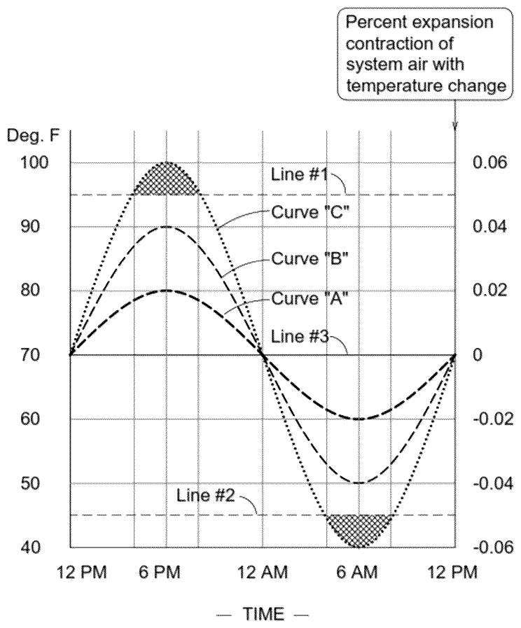

Referring to FIG. 3: This x-y chart shows an example of the environmental effect on the system air 41 properties from the relative seasonal temperature swings. The enclosure in this example is located within an outdoor mechanical room that may range in temperature from 45° F. to 95° F. The system air 41 volume within an enclosure 30 has a volume of 1,000 cubic inches. That is shown at the Line 3 baseline temperature of 70° F. and is the same temperature as outside ambient air 40. The enclosure 30 has the invention apparatus 10 attached with a bladder 20 volume of 100 cubic inches that is 10% of the enclosure 30 volume. This example shows the bladder 20 slightly undersized to demonstrate what happens in that case. This enclosure 30 has mainly electronics 31 that do not produce much heat and the system air 41 temperature tends to follow the ambient air temperature 40.

Temperature changes over a typical day are shown over an average 24-hour day, for example, for mild, above average, and peak extremes in daily temperatures as shown in sine wave type Curves A, B, and C.

The (x) baseline temperature Line 3 is 70° F. Line 3 also represents atmospheric pressure at 14.7 psia when at sea level. This is shown as zero (0) gage pressure (psi). The 100 cubic inches maximum capacity volume bladder 20 at this temperature and pressure would be half full at 50 cubic inches.

Curve A represents the system air temperature, during the mild or majority of the year, say 70% of the time where daily temperature swings are mild and may be 60° F. to 80° F. or less (20° F. swing). The system air 41 volume may vary between 1020 cubic inches to 980 cubic inches. The bladder volume may vary between 70 cubic inches to 30 cubic inches to accommodate the volume change while keeping the system air 41 pressure the same as ambient air pressure 40.

Curve B represents the above-average portion of the year, say 25% of the time where daily temperature swings may be 50° F. to 90° F. or less (40° F. swing). The system air 41 volume may vary between 1040 cubic inches to 960 cubic inches. The bladder volume may vary between 80 cubic inches to 10 cubic inches.

Curve C represents the above peak extremes portion of the year, say 5% of the time, where daily temperature swings may be 40° F. to 100° F. or less (60° F. swing). The system air 41 volume may vary between 1060 cubic inches to 940 cubic inches. However, the bladder 20 volume may vary between 100 cubic inches to 0 cubic inches, (full or empty). That bladder 20 sizes may accommodate the system air 41 change from 950 cubic inches to 1050 cubic inches. Thus, 10 cubic inches of system air 41 leaks out, and 10 cubic inches of ambient air 40 leaks in. In this example, the bladder has reached its protection limit at 95° F. shown at Line 1, and 45° F. at Line 2.

The shaded portion of Curve C, above Line 1, indicates excess system air 41 escaping to ambient air 40 through the pressure/vacuum relief valve 28. The shaded portion of Curve C, below Line 2, indicates negative system air 41 pressure that causes ambient air 40 to enter into enclosure 30 through the pressure/vacuum relief valve 28.

The system air 41 and ambient air 40 remain at the same pressure between Line 1 and Line 2, and no leakage occurs in or out of enclosure 30. The small amount of ambient air 40 that entered the enclosure 30, shown shaded below Line 2 may represent less than 2% of prior art technology. That is a substantial improvement over prior art. If the bladder were sized at 12% (120 cubic inches) instead of 10% of the system air 41 volume, virtually no leakage would occur. Likewise, if the bladder were sized at 8% (80 cubic inches) it would protect against leakage for Curves A and B and most of Curve C. Therefore, it becomes apparent that even a small undersized bladder can substantially minimize air leakage into enclosure 30.

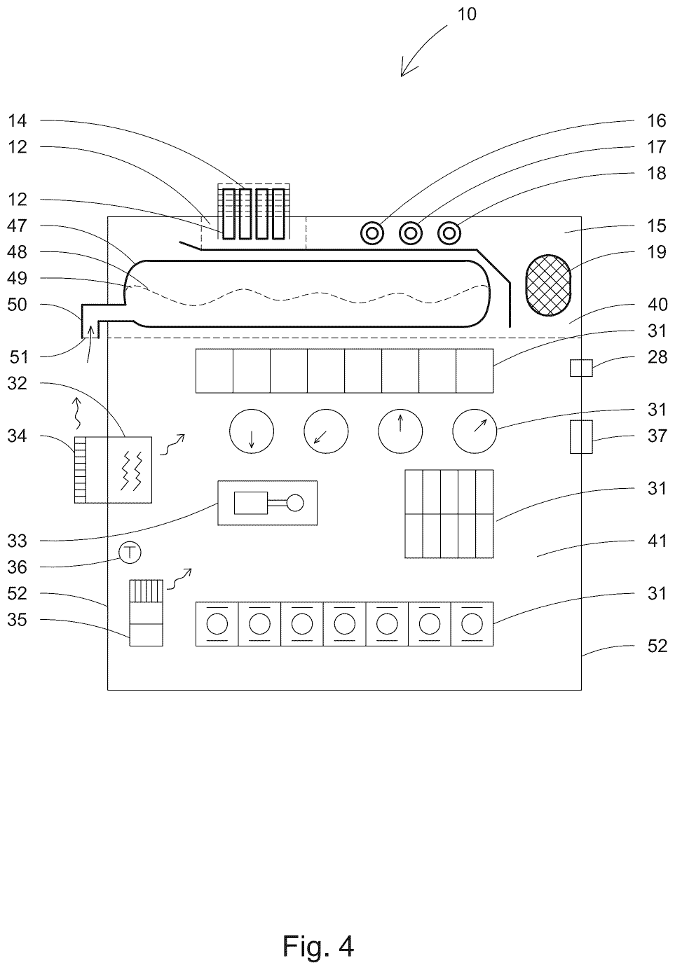

Referring to the FIG. 4 schematic diagram, is a variation of the invention apparatus 10 that shows the bladder 47 within the constant volume enclosure 52 instead of in an attachment apparatus. In this variation, the internal air within the bladder 47 is in fluid communication with ambient air 40. This variation simply provides the displacement volume of bladder 47 to maintain a constant enclosure 52 volume equal to the system air 41 and ambient air 48 within bladder 47 to equal the interior volume of the enclosure 52. The bladder 47 has an open vent port 50 extended into the ambient air 40. The system air 41 within the enclosure would be at maximum volume with the bladder 47 empty or fully deflated. The system air 41 within the enclosure 52 would be at minimum volume with the bladder 47 full of ambient air 40. In this variation, most of the other features of the invention, including the cooling chamber 12 and the treatment chamber 15 remain the same but are within the enclosure 52. This variation would have primary application for new enclosure 52 where a portion of the enclosure 52 would include space for the bladder 47 and the other invention components. This built-in feature would substantially reduce field labor costs that would be required to add the invention apparatus at a later date. For new enclosures 52, this may be the preferred form of the invention. The bladder 47 size is desirably sized based on expected temperature exposure changes and may, for example, range between 10% to 20% of the internal volume of the enclosure 52. The bladder 47 size may be more or less depending on the specific application and environmental exposure conditions.

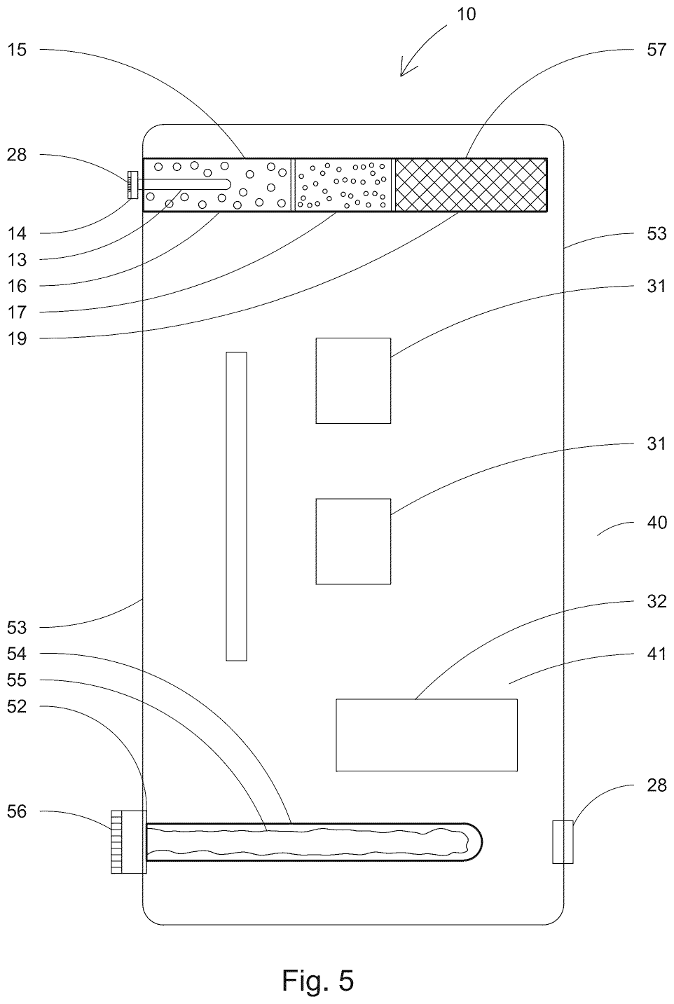

Referring to FIG. 5 shows a variation of the invention within a very small enclosure 53 that may be the size of a cell phone for example. The small bladder 54 has an inlet port 56 that would be in fluid communication with ambient air 40. The small bladder 54 fully inflated with ambient air 40 maybe 10% of the volume of the internal system air 41 within the enclosure 53. The evaporator portion of heat pipe 13 is shown within a removable perforated cartridge that contains the treatment chamber 15 which may include the desiccant 16, oxygen absorber 17 and filter 19. The condenser portion of the heat pipe 14 is shown as an exterior knob or plug that connects to the interior of the small enclosure 53. The bladder 54 and other invention components may be of a wide array of designs, shapes, and sizes. As the industry continues to streamline electronic, digital, and other products with LEDs and other components that produce less heat this invention can be very protective against water ingression that may be very damaging to lithium-type batteries and other components. The pressure/vacuum valve 28 may be built into the heat pipe condenser knob 14.

Enclosures 30 may be used in applications where internal components 31, 32, and 33 produce erratic heat increases that far exceed the heat dissipating capacity of the heat pipes 13, 14. The term “air conditioning” as used herein includes vapor-compression refrigeration systems. Air conditioning units, although expensive and require maintenance can be used to keep the enclosure 30 within certain temperature limits. These systems can recirculate system air but pressure differentials result in air leakage the higher the temperature differential.

Enclosures 30 used in applications with low heat producing components 31 and that require occasional door openings may not utilize all the items in the treatment chamber 15. For example, the oxygen absorber 17 may be quickly in need of replacement if exposed to too much ambient air 40.

This invention has been described as protecting mainly enclosures 30 related to electronic, electric, mechanical mechanisms, and controls from airborne contamination, however, many other types of enclosures 30, housings, cases, containers, and related items may also benefit from the use of his invention. For example, long range storage of missiles, weapons, bombs, need to be ready for use on a moment's notice. This apparatus in accordance with the present invention may include a quick connecting attachment to a port in fluid communication to the internal system air 41 of the object to be protected. Preventing airborne contaminants from contacting and damaging certain items of high value, sensitive, delicate, rare, historical, critical, irreplaceable, or other stored items for long periods of time will benefit from the apparatus in accordance with the present invention.

The pressure/vacuum relief valves may be set to plus 0.1 psi and minus 0.1 psi or other desired settings.

Example of a typical fixed 1,000 cubic inch volume NEMA 4 enclosures without the attached variable volume invention apparatus: The volumetric expansion of the system air within the enclosure is approximately 0.002 per degree F. If the system air within the enclosure and ambient air starts off being equal at 70° F. and the pressure is 0 psig, then the system air heats up due to internal heat gains and becomes 100° F. or 30° F. degrees higher than ambient air, that is still at 70° F. and 0 psig, the system air volume would increase by 6 percent to 1,060 cubic inches and the pressure increase to 0.06 psig. Since the enclosure may be considered tight, but not leakproof, up to 6% of the original volume or 60 cubic inches would leak out of the enclosure and the pressure may drop back to 0 psig while still at 100° F. Then when the system air cools back down to 70° F. the pressure may drop to −0.06 psig and 60 cubic inches of ambient air would leak back into the enclosure. This process may be repeated multiple times per day and result in significant volumes of ambient air leaking into the enclosure.

Every enclosure system's air temperature and pressure will inherently be governed by the general gas laws. These laws consist of three primary laws: Charles' Law, Boyle's Law, and Avogadro's Law (all of which will later combine into the General Gas Equation and Ideal Gas Law).

This is where the General Gas Laws have application:

Pressure times Volume divided by Temperature=Constant, or.

P×V/T=constant. For IP (Inch-Pound): Absolute Pressure (P) is used and is 14.7 psi at sea level. Absolute Temperature (T) in Kelvin or (F—460). Since the enclosure has a fixed internal system air volume (V), and the enclosure pressure (P) has to be the same or close to the ambient air pressure, to avoid damaging the enclosure, air leakage has to occur. Since the enclosure has a fixed system air volume, any increase or decrease in the temperature will cause a corresponding pressure change resulting in air leaking into or out of the enclosure.

Advantages of this invention apparatus: The present invention keeps the pressure within the enclosure essentially the same as ambient air pressure over a broad range of temperature changes. There is virtually no air leakage when there is no pressure differential. A passive heat pipe cooling chamber rejects internal heat and causes air circulation. A treatment chamber treats the circulation system air to a clean dry state with a high concentration of nitrogen. With no entrance of ambient air that contains water, humid air, harmful particles, mold, pollen, dust, oxygen, and corrosive gasses, the treatment chamber only has to treat the internal system air so the enclosure is protected against the ambient air contaminants. The internal electronic components and sensitive connections will avoid oxidation and corrosion and have a long life. This results in keeping all components in an ideal environment with minimum maintenance and a fast payback.

All publications and patent applications mentioned in this specification are indicative of the level of skill of those skilled in the art to which this invention pertains. All publications and patent applications are herein incorporated by reference to the same extent as if each publication or patent application was specifically and individually indicated to be incorporated by reference.

Although the description above contains many specifics, these should not be construed as limiting the scope of the invention, but as merely providing illustrations of some of the presently preferred embodiments of this invention. Thus, the scope of this invention should be determined by the appended claims and their legal equivalents. Therefore, it will be appreciated that the scope of the present invention fully encompasses other embodiments which may become obvious to those skilled in the art and that the scope of the present invention is accordingly to be limited by the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

### REFERENCE NUMBERS

10 The enclosure is in accordance with one form of the present invention.
11. Ventilated housing with louvers allowing free gravity flow of ambient air. This ambient air has no contact and no impact on system air directly or indirectly with system air.
12. Cooling chamber or thermal siphon cooling chamber. This portion cools warm system air and contains the evaporator portion of the heat pipe. As the system air transfers heat energy to the evaporator portion of the heat pipe, the system air becomes cooler and denser and condensation may occur. This generates system airflow downward and creates a thermal siphon effect that circulates the system air as long as there is a temperature differential between system air and ambient air.
13. Evaporator portion or heat pipe. This transfers heat energy from warm or hot system air to the condenser portion of the heat pipe located outside the invention apparatus housing where the heat energy is transferred to ambient air. This cooling of system air increases its density which causes the system air to flow. Water molecules are attracted to the cooled surface of the evaporator portion of the heat pipe and the relative humidity will increase and water condensation may occur. Heat pipes may contain water as the heat transfer medium and can be used in applications where freezing conditions do not occur. Methanol and certain other transfer fluids can be used where freezing temperatures may occur. The evaporator portion may have fins for faster heat transfer. One or more heat pipes may be used.
14. The condenser portion of the heat pipe is located outside the invention housing where the heat energy is transferred to ambient air. The condenser portion may have fins for faster heat transfer. One or more heat pipes may be used.
15. Treatment Chamber. This is an expanded portion of the conduit-carrying system air. This contains the system air treatment cartridges to remove water and other airborne contaminants. The cartridges may extend through the ventilated housing for easy inspection and replacement or a door on the housing can allow access for service.
16. Drier cartridge: Desiccant, which may be silica gel and may be in a cartridge within a perforated shell that allows system air to flow around and or through the cartridge to capture water molecules. The shell cap may have a moisture indicator that shows the condition of the desiccant or color change desiccant may be used. The cartridge fits into the treatment chamber.
17. Oxygen absorber cartridge: Oxygen Absorber, Type D, in permeable packets in a cartridge within the perforated shell. Captures oxygen molecules from system air thereby increasing the nitrogen concentration. The shell cap may have an oxygen indicator that shows the condition of the oxygen absorber packets. The cartridge fits into the treatment chamber.
18. Replaceable Treatment Cartridge: Activated carbon or site-specific media in a cartridge within a perforated shell. Captures hydrocarbon molecules or other gases such as ammonia. The cartridge fits into the treatment chamber.
19. Replaceable Filter Cartridge: Impingement filter. Air flows over, through, and/or by-passes to avoid or minimize any air resistance. The filter may contain foam, microfiber, or static attractive material. The cartridge fits into the treatment chamber.
20. Variable volume device: As used herein the term “variable volume device” will be understood to be a bladder, expansion chamber, or air displacement device. This device maintains the system air pressure to be the same as the ambient air pressure as long as the bladder or equivalent is not fully inflated or deflated. The interior of the bladder, expansion chamber, or air displacement device is in fluid communication with system air while the exterior of the bladder is exposed to ambient air. It is shown as fully inflated. It is sized to more than compensate for the normal maximum system air volume expansion or displacement volume due to daily system air temperature changes. It may be lightweight and made with a non-expanding material such as urethane-coated nylon fabric, or a poly product. This allows it to inflate or deflate with a fraction of an inch water column pressure. When fully inflated, and under pressure, the bladder reaches a fixed maximum volume. Any additional expansion of the system air will cause the pressure to increase and that may activate the pressure vacuum relief valves.
21. Variable volume device, bladder, expansion chamber or air displacement device in fluid communication with system air. It is shown partially inflated.
22. Wear protection covering all or part of a bladder. The bladder may have a protective fabric or plastic wear sleeve or covering to prevent damage to the bladder from repeated contact with surrounding surfaces as it inflates and deflates.
23. Conduit for system providing fluid communication between ambient with a variable volume device such as a bladder.
24. Conduit leading to cooling chamber.
25. Conduit leaving treatment chamber.
26. Conduit connection on bottom of apparatus to top of enclosure for circulating system air between enclosure and the apparatus of the present invention.
27. Return system air conduit near top of enclosure for treated system air return flow into enclosure.
28. Pressure/vacuum relief valves (PVRV). These may be set for plus 0.1 psi and minus 0.1 psi or 2.7″ water column. The differential pressure between these plus and minus pressure settings equal 0.2 psi. These pressure settings will generally not be reached unless the bladder in undersized or the temperature exceeds design limits or the elevation changes to extremes; changes in barometric pressure or high wind velocity pressure. Small enclosures may generally have a higher-pressure setting than large enclosures. Note: A 100 square inch door at plus 0.1 psi would have a force of 10 pounds against the door. The same door at minus 0.1 psi would have 10 pounds force holding it closed. A push button relief feature on the pressure relief valve should be pressed to relieve and equalize pressure before opening the door of the enclosure. The door latch or other items may also have this pressure relief feature for safety. A Halkey Roberts Model 790ZSP automatic dual action valve with a push button pressure relief exemplifies apparatus to be operated by a user before opening the enclosure door. Minivalve, Inc. provides a simple low-cost pressure relief, breather, duckbill, umbrella, balls and other valves.
29. Ventilation louvers in apparatus housing. These allow ambient air to flow in and out of the apparatus housing without coming in contact with system air.
30. Enclosure. This may be an instrument, electrical or other type enclosure that houses various equipment components such as, controls, transformers, electronics, wiring, connectors and more components that are preferably protected against environmental contamination, water, high humidity, high and low temperatures and high and low pressures. The enclosure may have, for example, a NEMA 4 rating with door and gaskets and may be weather resistant but not tight against air leaks when under a negative or positive air pressure. Provisions should be made to allow for limits on allowable internal temperatures and pressures for safety and to avoid damage or other problems to components or the enclosure door.
31. Components in an enclosure that may be sensitive to environmental related contamination including water condensation, high humidity, oxidation, or dust particles. This includes optical equipment, lens, glass viewports, electronics, lasers, terminal connections, robotics, and many other types of parts.
32. Components in a housing that have control terminal connections or generate heat such as transformers, work items, lights, electrical heat losses, and other heat-producing items. These may include thermoelectric cooling devices to reject heat to ambient air.
33. Components in the housing that have moving parts such as gears, levers, and mechanisms that may have tight tolerances, Thus, water and other contaminants may cause damage or wear.
34. Some embodiments of the invention utilize a thermoelectric cooling device (Peltier cooler) to transfer heat from a heat-producing component to ambient air.
35. Optional with certain enclosures: Electric heater that turns on when the system air temperature reaches a certain minimum temperature setting. Commonly used in freezing weather conditions.
36. Optional with certain enclosures: Thermostat to control system air temperature within certain limits.
37. Enclosure doors, hinges, latches, penetrations, knobs, and other attachments may be a source of air leaks.
38. Enclosure gasket.
39. Enclosure gauges.
40. Ambient air. It may be at sea level elevation at 14.7 psia pressure. The temperature may vary widely from well below freezing to well over 100° F. Daily temperature swings may vary widely and may exceed 60° F. degrees from day to night. The relative humidity may vary widely from very low to saturation or dew point. The ambient air environment may include exposures to rain, snow, sleet, dust, salt spray, gasses, mists, PM10, PM2.5, sub-micron particles, and various other contaminants in factories, marine, deserts, farms, processing plants, vehicles, artic, industrial and commercial and more. Airborne contaminants from these above sources can damage enclosure components and the invention apparatus's goal is to stop or minimize entry of ambient air and contaminants into the enclosure and to capture any that enter.
41. System air. The system air is within the enclosure and in fluid communication within the conduit system, cooling chamber, treatment chamber, and bladder within the invention apparatus. The goal of the present invention is to keep ambient air from leaking into the enclosure and system air from leaking out of the enclosure and to help keep it clean and dry, within certain temperature limits, equal in air pressure with outside air.
42. System air in conduit to the bladder in the apparatus and within the bladder. This is the plus or minus displacement volume of system air due to temperature, pressure, and elevation changes.
43. Warm or hot system air in conduit leading to the cooling chamber.
44. Cooled system air in the cooling chamber.
45. Cooled and treated system air in treatment chamber. The system air is partially exposed to a desiccant, oxygen absorber, activated carbon, and a filter where part of flow is bypassed around, over, and through the various treatment items so as not to cause a restrictive pressure drop. Even though the circulating system air may flow at a very slow rate through the treatment chamber because this is a closed recirculating system, the number of contaminants within the system air will remain very low even with inefficient treatment devices.
46. The cooled and treated system air re-enters the enclosure and mixes with the warmer system air within the enclosure.
47. Air displacement device. This may be an impermeable membrane or bladder that is located within the enclosure to form a cavity. The port of the bladder would have an opening to outside ambient air. This would allow ambient air to enter or leave the bladder or air displacement device whenever there was a change in temperature or pressure so that the system air in the enclosure plus the ambient air in the air displacement device is at a constant volume.
48. Air displacement device is shown partially inflated.
49. Ambient air within a bladder. The system air volume plus air volume within the bladder is constant. This allows the enclosure's internal air pressure and ambient air pressure to be the same during normal limit of temperature and pressure.
50. Ambient air inlet and outlet conduit to air displacement device within the enclosure.
51. Ambient air inlet for bladder. This may have a louver, filter, or membrane to prevent certain particles from entering the bladder.
52. Enclosure with an embodiment of the present invention within the enclosure.
53. Small enclosure with an embodiment of present invention apparatus within the enclosure.
54. Bladder showed within small enclosure.
55. Bladder shown within small enclosure partially inflated.
56. Bladder inlet port to outside ambient air with filter.
57. A perforated containment device, that may be foam or other material that allows water molecules and oxygen in the system air to pass through to be captured by the desiccant and or oxygen absorber.
58. UVC-LED light helps sterilize microbes in circulating system air and sensitive electronic components, in some embodiments mainly for applications where enclosures are exposed to humid conditions and mold growth. This light is solar-powered in outdoor applications.
59. Variation of invention: Solar collector for powering UVC-LED light and interior LED lights.
60. Shrader valve: During the initial installation of the invention apparatus, the enclosure may be filled with nitrogen through a Schrader valve to purge air out of the enclosure.
61. Temperature gauge.
62. Relative humidity gauge.
63. Pressure gauge.

1. A method for preventing gas flow into and out of a first enclosure having an interior and an exterior and a first internal volume and a first internal pressure by limiting changes of the pressure within the interior of the first enclosure which comprises:
providing a second enclosure including a variable volume device having an interior second volume that varies responsive to the pressures inside and outside the second enclosure;
providing fluid communication between the interior of the first enclosure and the interior of the second enclosure to maintain a substantially fixed collective volume of the combination the first enclosure and the second enclosure despite ambient temperature and/or pressure changes whereby the stability of the gas pressure minimizes movement of gases into or out of the collective volume of the fluid communication, the first enclosure and the second enclosure;
said method being capable of maintaining a fixed collective volume without any liquid phase substance.

2. The method as described in claim 1 wherein the step of providing a second enclosure having a second volume that varies responsive to the pressures inside and outside the second enclosure includes providing a bladder.

3. The method as described in claim 1 further includes providing a desiccant in fluid communication with the first enclosure.

4. The method as described in claim 1 further including providing a pressure relief valve in fluid communication with the first enclosure.

5. The method as described in claim 1 further including providing a vacuum relief valve in fluid communication with the first enclosure.

6. The method as described in claim 1 further including providing an air conditioning system for removal of heat from the first enclosure.

7. The method as described in claim 1 further including providing a cooperating evaporator and condenser which are part of apparatus selected from group consisting of heat pipes and thermoelectric coolers to remove heat from the first enclosure, said evaporator being disposed proximate said desiccant.

8. The method as described in claim 1 further including providing a thermostat to control the temperature within said the first enclosure.

9. The method as described in claim 1 further including providing a desiccant in fluid communication with the first enclosure.

10. The method as described in claim 1 further including providing a pressure relief valve in fluid communication with the first enclosure.

11. The method as described in claim 1 further including providing a vacuum relief valve in fluid communication with the first enclosure.

12. The method as described in claim 1 further including providing an air conditioning system for removal of heat from the first enclosure.

13. The method as described in claim 1 further including providing a device selected from the group consisting of heat pipes and thermoelectric cooling devices for removal of heat from the first enclosure.

14. The method as described in claim 1 further including providing a thermostat to control the temperature within the first enclosure.

15. A method for preventing gas flow into and out of a first enclosure having a first volume by limiting changes of the pressure within the first enclosure which comprises: providing a second enclosure having the interior thereof in fluid communication with the ambient air surrounding the first enclosure and disposed within the first enclosure, said second chamber having a volume that varies responsive to the fluid pressure within and outside of the second enclosure to maintain the pressure of gases within the first enclosure that are outside of said fluid tight chamber despite changes in the temperature of fluids therein whereby the stability of the gas pressure minimizes movement of gases into or out of said apparatus.

16. The method as described in claim 15 further including providing a desiccant in fluid communication with the said fluid tight chamber

17. The method as described in claim 15 further including providing a pressure relief valve in fluid communication with the first enclosure.

17. NO CLAIM 17 WAS IN THE APPLICATION

18. The method as described in claim 15 further including providing a vacuum relief valve in fluid communication with the first enclosure.

19. The method as described in claim 15 further including providing an air conditioning system for removal of heat from the first enclosure.

20. The method as described in claim 15 further including providing a device selected from the group consisting of thermoelectric cooling devices and heat pipes to remove heat from the first enclosure.

21. The method as described in claim 15 further including providing a thermostat to control the temperature within the first enclosure.
